(19) United States
(12) Patent Application Publication
(10) Pub. No.: US 2024/0088796 A1
(43) Pub. Date: Mar. 14, 2024

(54) SEMICONDUCTOR MODULE

(71) Applicant: FUJI ELECTRIC CO., LTD., Kanagawa (JP)

(72) Inventors: Yuhei NISHIDA, Matsumoto-city (JP); Mayumi SHIOHARA, Matsumoto-city (JP)

(21) Appl. No.: 18/511,954

(22) Filed: Nov. 16, 2023

Related U.S. Application Data
(63) Continuation of application No. PCT/JP2022/041620, filed on Nov. 8, 2022.

(30) Foreign Application Priority Data
Dec. 27, 2021 (JP) 2021-212199

(51) Int. Cl. H02M 7/00; H01L 23/00; H01L 25/07

(52) U.S. Cl. CPC H02M 7/003; H01L 24/48; H01L 24/49; H01L 25/072; H01L 2224/48137; H01L 2224/49113; H01L 2224/49177; H01L 2924/19107; H01L 2924/30107

(57) ABSTRACT

Provided is a semiconductor module, including: a first switching device provided in one of an upper arm or a lower arm; a second switching device provided in another of the upper arm or the lower arm; a first diode device provided in parallel with the first switching device; a second diode device provided in parallel with the second switching device; a laminated substrate of which a main surface has two sides extending in a predetermined first direction and a predetermined second direction; and a gate external terminal and an auxiliary source external terminal provided farther toward a negative side of the first direction than the upper arm and the lower arm, and arranged in the second direction.

The contents of the following patent application(s) are incorporated herein by reference:
NO. 2021-212199 filed in JP on Dec. 27, 2021
NO. PCT/JP2022/041620 filed in WO on Nov. 8, 2022

### BACKGROUND

### 1. Technical Field

The present invention relates to a semiconductor module.

### 2. Related Art

Conventionally, a semiconductor module on which a switching device is mounted is known (for example, see Patent Documents 1 to 3).
Patent Document 1: International Publication No. 2015/136603
Patent Document 2: Japanese Patent Application Publication No. 2000-324846
Patent Document 3: Japanese Patent Application Publication No. 2021-019094

### BRIEF DESCRIPTION OF THE DRAWINGS

FIG. 1A illustrates an overview of structure of a semiconductor module 100.

FIG. 1B illustrates one example of an enlarged view of a semiconductor assembly 160.

FIG. 1C illustrates one example of a cross section a-a′ of the semiconductor assembly 160 illustrated in FIG. 1B.

FIG. 1D is a main circuit diagram of the semiconductor module 100 according to an embodiment.

FIG. 2 illustrates current/voltage characteristics at times of switching the semiconductor module 100.

FIG. 3A is a circuit diagram taken at time T1 of FIG. 2, which shows an ON state of a switching device 10 placed in an upper arm 102.

FIG. 3B is a circuit diagram taken at time T2 of FIG. 2, which shows an OFF state of the switching device 10 placed in the upper arm 102.

FIG. 3C is a circuit diagram taken at time T3 of FIG. 2, which shows an ON state of the switching device 10 placed in the upper arm 102.

FIG. 3D is one example of a top view of the semiconductor assembly 160 with a reverse recovery current Irr flowing in a lower arm 104 in response to the upper arm 102 being turned on.

FIG. 4A is a circuit diagram taken at time T1 of FIG. 2, which shows an ON state of the switching device 20 placed in the lower arm 104.

FIG. 4B is a circuit diagram taken at time T2 of FIG. 2, which shows an OFF state of the switching device 20 placed in the lower arm 104.

FIG. 4C is a circuit diagram taken from time T2 to time T3 of FIG. 2, which shows an ON state of the switching device 20 placed in the lower arm 104.

FIG. 4D is one example of a top view of the semiconductor assembly 160 with a reverse recovery current Irr flowing in the upper arm 102 in response to the lower arm 104 being turned on.

FIG. 5A is an enlarged view of a variant example of the semiconductor assembly 160.

FIG. 5B is an enlarged view of a variant example of the semiconductor assembly 160.

FIG. 6A is an enlarged view of a variant example of the semiconductor assembly 160.

FIG. 6B is an enlarged view of a variant example of the semiconductor assembly 160.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are imperative to the solving means of the invention.

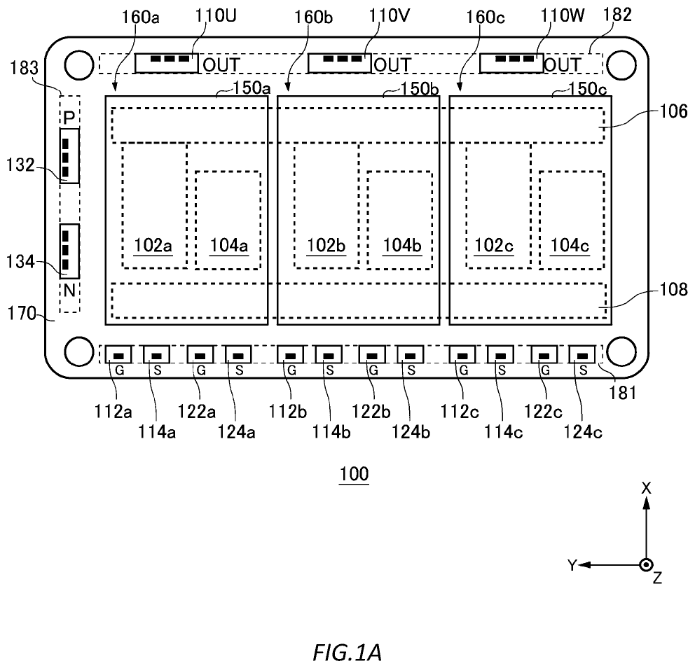

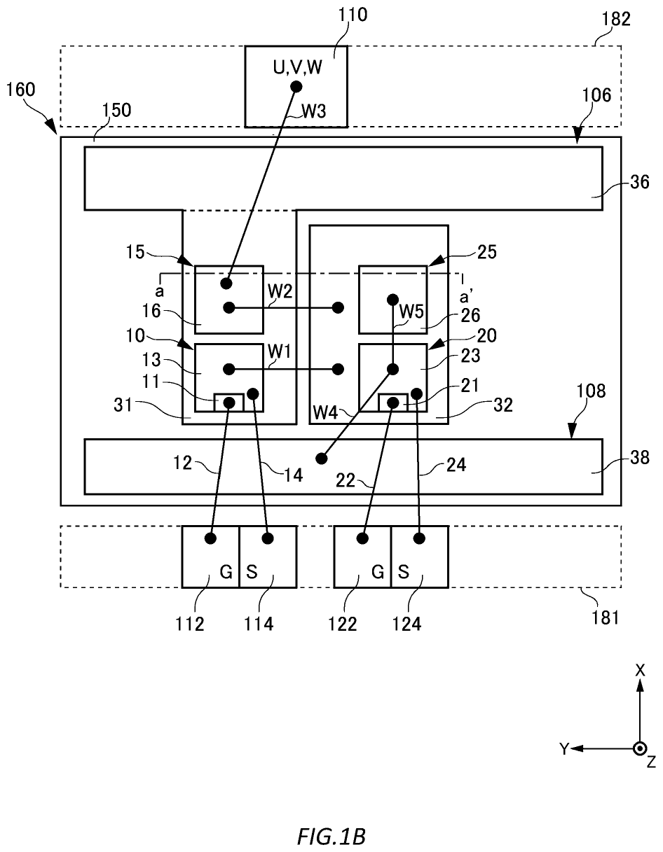

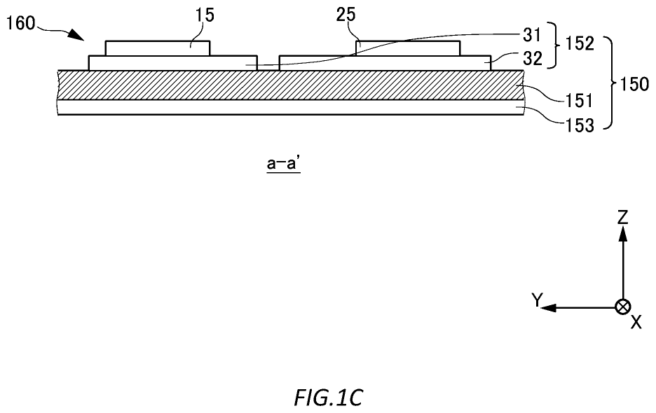

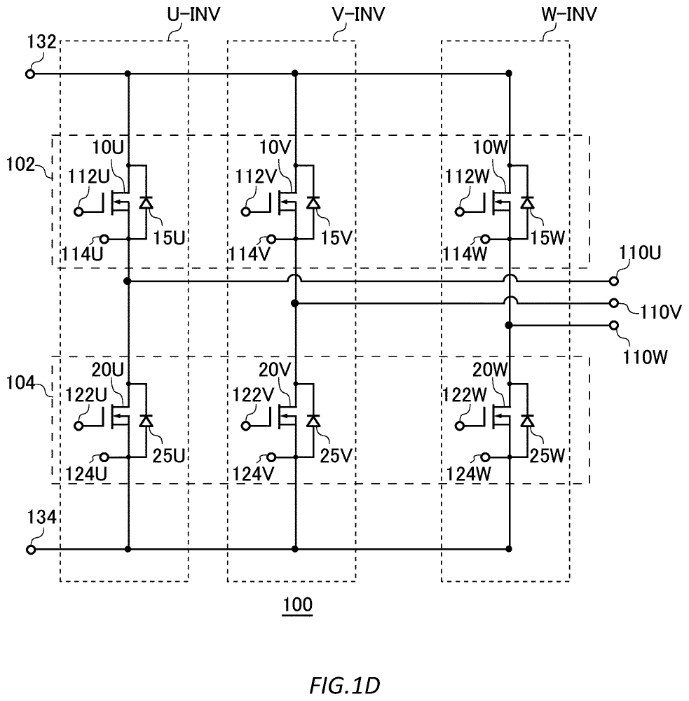

FIG. 1A illustrates an overview of structure of a semiconductor module 100. The semiconductor module 100 includes multiple semiconductor assemblies 160. Even though the semiconductor module 100 of the present example includes three semiconductor assemblies 160a to 160c, it is not limited to include three semiconductor assemblies. The semiconductor module 100 of the present example includes output terminals 110, a positive electrode terminal 132, a negative electrode terminal 134, gate external terminals 112, auxiliary source external terminals 114, gate external terminals 122, and auxiliary source external terminals 124, as external terminals.

The semiconductor module 100 may be applied to a power conversion device such as a power module constituting an inverter circuit. For example, when the semiconductor module 100 constitutes a three-phase inverter circuit, the semiconductor assemblies 160a to 160c may correspond to a U phase, a V phase, and a W phase of the three-phase inverter circuit, respectively.

A semiconductor assembly 160 has a laminated substrate 150. The laminated substrate 150 is provided with an upper arm 102, a lower arm 104, a P type wiring portion 106, and an N type wiring portion 108. The semiconductor assembly 160 is accommodated in a housing 170 of the semiconductor module 100. The semiconductor assembly 160 may be encapsulated in the housing 170 by means of an arbitrary encapsulation resin material.

Switching devices and diode devices to be described later are mounted on the laminated substrate 150. A main surface of the laminated substrate 150 has two sides which extend in a predetermined first direction (e.g. X axis direction) and a predetermined second direction (e.g. Y axis direction). In other words, the laminated substrate 150 of the present example has the main surface on an XY plane. Even though the first direction and the second direction are respectively described as the X axis direction and the Y axis direction in the present example, the first direction and the second direction are not limited to these.

The laminated substrate 150 may be a direct copper bonding (DCB) substrate or an active metal brazing (AMB) substrate. Even though the semiconductor module 100 of the present example includes three laminated substrates 150a to 150c arranged in the Y axis direction, the number and an arrangement method of the laminated substrates 150 are not limited to these.

The semiconductor module 100 includes multiple legs each of which is constituted by an upper arm 102 and a lower arm 104. Even though the semiconductor module 100 of the present example includes three legs, the number of legs is not limited to this. Each of the multiple legs is placed on the laminated substrates 150a, 150b, and 150c. Upper arms 102a to 102c are provided to the laminated substrates 150a to 150c, respectively. Lower arms 104a to 104c are provided to the laminated substrates 150a to 150c, respectively. The multiple legs may be mounted on one laminated substrate 150.

The output terminals 110 are external terminals used for electrically connecting to loads provided outside the semiconductor module 100. The output terminals 110 of the present example has three external terminals being an output terminal 110U, an output terminal 110V, and an output terminal 110W, which correspond to the U to W phases, respectively. The output terminals 110 are provided on one predetermined side of the semiconductor module 100. Among four sides of the semiconductor module 100, the output terminals 110 of the present example are provided on a side that extends in the Y axis direction on a positive side of an X axis direction. In other words, the output terminals 110 are provided farther toward the positive side of the X axis direction than the upper arms 102 and the lower arms 104. The output terminals 110 of the present example are provided in a second placement region 182 that extends in the Y axis direction. The multiple output terminals 110 are arranged in the Y axis direction in the second placement region 182.

The three output terminals 110U to 110W are arranged in the Y axis direction such that the output terminals 110U to 110W face the laminated substrates 150a to 150c, respectively. Note that, the number and an arrangement method of the output terminals 110 are not limited to these.

The gate external terminals 112, the auxiliary source external terminals 114, the gate external terminals 122, and the auxiliary source external terminals 124 are examples of control terminals which control operation of the semiconductor module 100. The control terminals of the present example are provided on a side opposite to the side on which the output terminals 110 are provided. The control terminals of the present example are provided on a side that extends in the Y axis direction of the semiconductor module 100, on a negative side of an X axis direction. In other words, the gate external terminals 112, the auxiliary source external terminals 114, the gate external terminals 122, and the auxiliary source external terminals 124 are provided farther toward the negative side of the X axis direction than the upper arms 102 and the lower arms 104.

The gate external terminals 112 have three gate external terminals 112a to 112c, which correspond to the laminated substrates 150a to 150c, respectively. The auxiliary source external terminals 114 have three auxiliary source external terminals 114a to 114c, which correspond to the laminated substrates 150a to 150c, respectively. The multiple gate external terminals 112 of the present example are provided in a first placement region 181 that extends in the Y axis direction. The multiple auxiliary source external terminals 114 of the present example are provided in the first placement region 181 that extends in the Y axis direction.

Similarly, the gate external terminals 122 have three gate external terminals 122a to 122c, which correspond to the laminated substrates 150a to 150c, respectively. The auxiliary source external terminals 124 have three auxiliary source external terminals 124a to 124c, which correspond to the laminated substrates 150a to 150c, respectively. The multiple gate external terminals 122 of the present example are provided in the first placement region 181 that extends in the Y axis direction. The multiple auxiliary source external terminals 124 of the present example are provided in the first placement region 181 that extends in the Y axis direction.

The positive electrode terminal 132 and the negative electrode terminal 134 are provided on one predetermined side of the semiconductor module 100. The positive electrode terminal 132 and the negative electrode terminal 134 of the present example are provided on a side orthogonal to the side on which the output terminals 110 are provided. The positive electrode terminal 132 and the negative electrode terminal 134 may be provided on a side orthogonal to the side on which the control terminals such as the gate external terminals 112 are provided. The positive electrode terminal 132 and the negative electrode terminal 134 of the present example are provided on a side that extends in the X axis direction, on a positive side of the Y axis direction of the semiconductor module 100. However, the positive electrode terminal 132 and the negative electrode terminal 134 can be provided on a side that extends in the X axis direction on a negative side of the Y axis direction. The positive electrode terminal 132 and the negative electrode terminal 134 of the present example are provided in a third placement region 183 that extends in the X axis direction. The third placement region 183 may be placed side by side with the multiple legs in the Y axis direction. In other words, the third placement region 183 may be provided facing the multiple legs in the Y axis direction. The positive electrode terminal 132 and the negative electrode terminal 134 are arranged in the X axis direction in the third placement region 183.

The P type wiring portion 106 is one example of a first wiring portion or a second wiring portion. The N type wiring portion 108 is one example of the first wiring portion or the second wiring portion. The first wiring portion is connected to one of the positive electrode terminal 132 or the negative electrode terminal 134, and extends in the Y axis direction. The second wiring portion is connected to another of the positive electrode terminal 132 or the negative electrode terminal 134, and extends in the Y axis direction. Note that, even though the P type wiring portion 106 and the N type wiring portion 108 are respectively described as the first wiring portion and the second wiring portion in the present example, the P type wiring portion 106 and the N type wiring portion 108 are not limited to these. Positions of the P type wiring portion 106 and the N type wiring portion 108 may be suitably swapped.

The P type wiring portion 106 is connected to the positive electrode terminal 132. The N type wiring portion 108 is connected to the negative electrode terminal 134. The P type wiring portion 106 and the N type wiring portion 108 are provided extending in the Y axis direction. The P type wiring portion 106 and the N type wiring portion 108 are provided such that the upper arms 102 and the lower arms 104 are sandwiched between the P type wiring portion 106 and the N type wiring portion 108 in the X axis direction. The P type wiring portion 106 is provided farther toward a positive side of the X axis direction than the N type wiring portion 108. That is to say, the P type wiring portion 106 is provided between the N type wiring portion 108 and the output terminals 110 in the X axis direction. Each upper arm 102 of the multiple legs may be connected to each output terminal 110 by means of a wire member over the P type wiring portion 106.

The semiconductor module 100 includes the multiple upper arms 102 and the multiple lower arms 104. The multiple upper arms 102 and the multiple lower arms 104 are alternately arranged one by one in the Y axis direction. In this manner, a switching device 10 of an upper arm 102 and a switching device 20 of a lower arm 104 are alternately placed in the Y axis direction. With regard to the switching devices 10 and 20, they will be described later.

FIG. 1B illustrates one example of an enlarged view of the semiconductor assembly 160. The semiconductor module 100 may include multiple semiconductor assemblies 160 having structure the same as the structure described in the present example. Note that, the structure of the semiconductor assembly 160 is schematically shown in the present example, so that a shape etc. of each component is not limited to that in the present example. The semiconductor assembly 160 includes the switching device 10, a diode device 15, the switching device 20, a diode device 25, and the laminated substrate 150.

The switching devices 10 and 20 are provided on the laminated substrate 150. The switching device 10 is one example of a first switching device provided in one of the upper arm 102 or the lower arm 104. The switching device 20 is one example of a second switching device provided in another of the upper arm 102 or the lower arm 104. Even though the present example describes about a case in which the switching device 10 is placed in the upper arm 102 and the switching device 20 is placed in the lower arm 104, the switching device 10 can be placed in the lower arm 104 and the switching device 20 can be placed in the upper arm 102. The switching devices 10 and 20 may be silicon carbide metal-oxide-semiconductors, or may also be other switching devices such as insulated gate bipolar transistors (IGBTs).

The switching device 10 has a gate electrode 11 and a source electrode 13 as front surface electrodes, and a drain electrode as a back surface electrode. The gate electrode 11 is connected to a gate external terminal 112 by means of a gate wiring member 12. The gate wiring member 12 is one example of a first gate wiring member which connects the gate electrode 11 of the switching device 10 and a corresponding gate external terminal 112 among the multiple gate external terminals 112. The source electrode 13 is connected to an auxiliary source external terminal 114 by means of an auxiliary source wiring member 14. The auxiliary source wiring member 14 is one example of a first auxiliary source wiring member which connects the source electrode 13 of the switching device 10 and a corresponding auxiliary source external terminal 114 among the multiple auxiliary source external terminals 114. The source electrode 13 is also connected to a circuit plate 32 by means of a wire member W1. The drain electrode of the switching device 10 is electrically connected to a circuit plate 31 by means of solder or the like.

The switching device 20 has a gate electrode 21 and a source electrode 23 as front surface electrodes, and a drain electrode as a back surface electrode. The gate electrode 21 is connected to a gate external terminal 122 by means of a gate wiring member 22. The gate wiring member 22 is one example of a second gate wiring member which connects the gate electrode 21 of the switching device 20 and a corresponding gate external terminal 122 among the multiple gate external terminals 122. The source electrode 23 is connected to an auxiliary source external terminal 124 by means of an auxiliary source wiring member 24. The auxiliary source wiring member 24 is one example of a second auxiliary source wiring member which connects the source electrode 23 of the switching device 20 and a corresponding auxiliary source external terminal 124 among the multiple auxiliary source external terminals 124. The source electrode 23 is also connected to a circuit plate 38 by means of a wire member W4, and to an anode electrode 26 by means of a wire member W5. The drain electrode of the switching device 20 is electrically connected to a circuit plate 32 by means of solder or the like.

The diode device 15 is one example of a first diode device provided in parallel with the switching device 10 on the laminated substrate 150. The diode device 15 functions as a reflux diode of the switching device 10. The diode device 15 of the present example has an anode electrode 16 as a front surface electrode and a cathode electrode as a back surface electrode. The anode electrode 16 is connected to the circuit plate 32 by means of a wire member W2. The anode electrode 16 is connected to an output terminal 110 by means of a wire member W3. The wire member W3 of the present example connects the output terminal 110 and the diode device 15 over the P type wiring portion 106. The cathode electrode of the diode device 15 is electrically connected to the circuit plate 31 by means of solder or the like.

The diode device 25 is one example of a second diode device provided in parallel with the switching device 20 on the laminated substrate 150. The diode device 25 functions as a reflux diode of the switching device 20. The diode device 25 of the present example has the anode electrode 26 as a front surface electrode and a cathode electrode as a back surface electrode. The anode electrode 26 is connected to the source electrode 23 of the switching device 20 by means of the wire member W5. The cathode electrode of the diode device 25 is electrically connected to the circuit plate 32 by means of solder or the like.

Even though the present example describes about a case in which the diode device 15 is placed in the upper arm 102 and the diode device 25 is placed in the lower arm 104, the diode device 15 can be placed in the lower arm 104 and the diode device 25 can be placed in the upper arm 102. The diode devices 15 and 25 may be silicon carbide Schottky barrier diodes, or freewheeling diodes (FWDs) formed on a silicon substrate.

The switching devices 10 and 20 are placed between the P type wiring portion 106 and the N type wiring portion 108 in the X axis direction. Similarly, the diode devices 15 and 25 are placed between the P type wiring portion 106 and the N type wiring portion 108 in the X axis direction. However, a semiconductor device on the laminated substrate 150 can be provided in the P type wiring portion 106 or the N type wiring portion 108. This semiconductor device may refer to the switching device 10, the diode device 15, the switching device 20, or the diode device 25.

The switching devices 10 and 20 are provided such that the P type wiring portion 106 is sandwiched between the switching devices 10 and 20, and the second placement region 182. The switching devices 10 and 20 are provided such that the N type wiring portion 108 is sandwiched between the switching devices 10 and 20, and the first placement region 181. The diode device 15 may be provided such that the switching device 10 is sandwiched between the diode device 15 and the N type wiring portion 108. The diode device 25 may be provided such that the switching device 20 is sandwiched between the diode device 25 and the N type wiring portion 108.

Here, at least one semiconductor device provided in the upper arm 102 is provided facing at least one semiconductor device provided in the lower arm 104 in the Y axis direction. For example, at least one of the switching device 10 or the diode device 15 is provided facing at least one of the switching device 20 or the diode device 25 in the Y axis direction.

The switching device 10 of the present example is provided facing the switching device 20 in the Y axis direction. In this manner, in the semiconductor module 100, the switching devices 10 and 20 have equal path lengths for control current, and thereby difference in switching losses between the upper arm and the lower arm can be reduced. Furthermore, even if the semiconductor module 100 has the multiple legs, switching losses are easily equalized between the multiple legs. For example, by providing the switching devices 10 and 20 so as to face each other in the Y axis direction, start-up times can be equalized at times of being turned on.

The switching device 10 and the diode device 15 are provided facing each other in the X axis direction. The diode device 15 of the present example is provided facing the diode device 25 in the Y axis direction. Like this, by carefully considering placement of the semiconductor devices on the laminated substrate 150, the semiconductor module 100 is easily miniaturized.

Note that, such a phrase as “the semiconductor devices are provided facing each other in the Y axis direction” may include a case in which at least a part of one semiconductor device is provided facing another semiconductor device in the Y axis direction. In addition, such a case in which semiconductor devices facing each other completely overlap together in the Y axis direction may be included.

The switching devices 10 and 20 may be placed so that a path length of the gate wiring member 12 is approximately equal to a path length of the gate wiring member 22. The gate electrode 11 and the gate electrode 21 may be provided facing each other in the Y axis direction. By providing the gate electrode 11 and the gate electrode 21 so as to face each other in the Y axis direction, their path lengths to the control terminals are easily equalized. Furthermore, a connection point for the gate electrode 11 and the gate wiring member 12 may be provided facing a connection point for the gate electrode 21 and the gate wiring member 22 in the Y axis direction. Note that, even though another device such as a semiconductor chip is not provided between the gate electrode 11 and the gate electrode 21 of the present example, the another device can be provided between the gate electrode 11 and the gate electrode 21. Even though both of the gate electrode 11 and the gate wiring member 12 are placed on a negative side of the X axis direction in the switching device, on an upper surface of the switching device, their placement is not limited to this.

Similarly, the switching devices 10 and 20 may be placed so that a path length of the auxiliary source wiring member 14 is approximately equal to a path length of the auxiliary source wiring member 24. The source electrode 13 and the source electrode 23 may be provided facing each other in the Y axis direction. By providing the source electrode 13 and the source electrode 23 so as to face each other in the Y axis direction, their path lengths to the control terminals are easily equalized. Further, a connection point for the source electrode 13 and the auxiliary source wiring member 14 may be provided facing a connection point for the source electrode 23 and the auxiliary source wiring member 24 in the Y axis direction. Note that, even though another device such as a semiconductor chip is not provided between the source electrode 13 and the source electrode 23 of the present example, the another device can be provided between the source electrode 13 and the source electrode 23.

In the semiconductor module 100 of the present example, by equalizing path lengths of the gate wiring members and the auxiliary source wiring members, path lengths for control current are equalized and thereby difference in switching losses between the upper arm and the lower arm can be reduced. By placing the switching devices 10 and 20 closer to the first placement region 181 than the diode devices 15 and 25, the path lengths for the control current are shortened, and thereby the path lengths are more easily equalized.

The gate wiring member 12 is electrically connected to the gate electrode 11 of the switching device 10. The gate wiring member 12 of the present example directly connects the gate electrode 11 and the gate external terminal 112 by means of a wire member. A gate current Ig which flows from the gate external terminal 112 toward the switching device 10 flows in the gate wiring member 12. The gate wiring member 12 may be composed of a combination of the wire member and a circuit plate 152 to be described later.

The auxiliary source wiring member 14 is connected to the source electrode 13 of the switching device 10. The auxiliary source wiring member 14 of the present example directly connects the source electrode 13 and the auxiliary source external terminal 114. An auxiliary source current Is which flows from the switching device 10 toward the auxiliary source external terminal 114 flows in the auxiliary source wiring member 14. In response to the gate current Ig flowing from the control terminal to the switching device 10, the auxiliary source current Is returns from the switching device 10 to the control terminal. The auxiliary source wiring member 14 may be composed of a combination of a wire member and the circuit plate 152 to be described later.

The circuit plate 31 forms a circuit plate 152 on which the switching device 10 and the diode device 15 are mounted. In other words, the circuit plate 31 of the present example is used to constitute the upper arm 102. The circuit plate 31 is electrically connected to the back surface electrodes of the switching device 10 and the diode device 15 by means of conductive fixing members such as solder. The circuit plate 31 may be electrically connected to the positive electrode terminal 132. The circuit plate 31 is provided between the P type wiring portion 106 and the N type wiring portion 108 in the X axis direction. Even though the circuit plate 31 of the present example is provided coupling to a circuit plate 36 of the P type wiring portion 106, the circuit plate 31 can be provided to be physically separated from the circuit plate 36.

The circuit plate 32 forms a circuit plate 152 on which the switching device 20 and the diode device 25 are mounted. In other words, the circuit plate 32 of the present example is used to constitute the lower arm 104. The circuit plate 32 is provided to be physically separated from the circuit plate 31. The circuit plate 32 is electrically connected to back surface electrodes of the switching device 20 and the diode device 25 by means of conductive fixing members such as solder. The circuit plate 32 is provided between the P type wiring portion 106 and the N type wiring portion 108 in the X axis direction. The circuit plate 32 is provided farther toward a negative side of the Y axis direction than the circuit plate 31.

The gate external terminal 112 is connected to the gate electrode 11 of the switching device 10 through the gate wiring member 12. The auxiliary source external terminal 114 is connected to the source electrode 13 of the switching device 10 through the auxiliary source wiring member 14. The gate external terminal 112 and the auxiliary source external terminal 114 are arranged in the Y axis direction. Even though the gate external terminal 112 is provided farther toward a positive side of the Y axis direction than the auxiliary source external terminal 114, the position of the gate external terminal 112 is not limited to this.

The gate external terminal 122 is connected to the gate electrode 21 of the switching device 20 through the gate wiring member 22. The auxiliary source external terminal 124 is connected to the source electrode 23 of the switching device 20 through the auxiliary source wiring member 24. The gate external terminal 122 and the auxiliary source external terminal 124 are arranged in the Y axis direction. Even though the gate external terminal 122 is provided farther toward a positive side of the Y axis direction than the auxiliary source external terminal 124, the position of the gate external terminal 122 is not limited to this.

The control terminals of the present example are arranged toward a negative side of the Y axis direction in this order of the gate external terminal 112, the auxiliary source external terminal 114, the gate external terminal 122 and the auxiliary source external terminal 124. In other words, gates and sources of the control terminals of the present example are arranged in order of GSGS (where G refers to a gate and S refers to a source). However, the gates and sources of the control terminals can be arranged in different order such as SGSG. The control terminals can be arranged toward a negative side of the Y axis direction in this order of the auxiliary source external terminal 114, the gate external terminal 112, the auxiliary source external terminal 124, and the gate external terminal 122. By arranging the control terminals in one line, degrees of freedom in wiring can be improved.

The switching device 10 may be placed closer to the control terminals than the diode device 15. The switching device 10 of the present example is provided farther toward a negative side of the X axis direction than the diode device 15. In other words, the switching device 10 is provided between the diode device 15 and the control terminals (e.g., the gate external terminal 112 and the auxiliary source external terminal 114) in the X axis direction. Furthermore, the switching device 10 is provided between the diode device 15 and the N type wiring portion 108 in the X axis direction. The switching device 10 may have the gate electrode 11 at a position close to the gate external terminal 112 on a chip.

Similarly, the switching device 20 may be placed closer to the control terminals than the diode device 25. The switching device 20 of the present example is provided farther toward a negative side of the X axis direction than the diode device 25. In other words, the switching device 20 is provided between the diode device 25 and the control terminals (e.g., the gate external terminal 122 and the auxiliary source external terminal 124) in the X axis direction. Furthermore, the switching device 20 is provided between the diode device 25 and the N type wiring portion 108 in the X axis direction. The switching device 20 may have the gate electrode 21 at a position close to the gate external terminal 122 on a chip.

The circuit plate 36 forms a circuit plate 152 provided in the P type wiring portion 106. The circuit plate 36 of the present example is one example of an extending portion provided extending in the Y axis direction. The circuit plate 36 of the present example is coupled to the circuit plate 31. The circuit plate 36 may be electrically connected to the positive electrode terminal 132 by means of a wire member. The multiple legs placed adjacent to each other may be directly connected via circuit plates 36, or by connecting the circuit plates 36 by wire members.

The circuit plate 38 forms a circuit plate 152 provided in the N type wiring portion 108. The circuit plate 38 of the present example is one example of the extending portion provided extending in the Y axis direction. The circuit plate 38 is electrically connected to the source electrode 23 by means of the wire member W4. The circuit plate 38 may be electrically connected to the negative electrode terminal 134 by means of a wire member. The multiple legs placed adjacent to each other can be directly connected via circuit plates 38, or by connecting the circuit plates 38 by means of wire members.

Here, the auxiliary source wiring member 14 of the present example is physically separated from an output wiring line between the drain electrode of the switching device 20 and the output terminal 110. The output wiring line may be a region having an electrical potential the same as that of the output terminal 110. The output wiring line may include the wire member W3 connected to the output terminal 110, and/or the circuit plate 32 on which the switching device 20 is placed. By physically separating the auxiliary source wiring member 14 from the output wiring line, impact from a reverse recovery current Irr that flows in the output wiring line can be avoided.

When a switching device of the semiconductor module 100 is turned on, the reverse recovery current Irr is generated in an arm opposite to an arm in which the switching device is placed. For example, when the switching device 10 is turned on, the reverse recovery current Irr flows in the switching device 20 opposite to the switching device 10. With regard to the reverse recovery current Irr, it will be described later.

In the semiconductor module 100 of the present example, by physically separating the auxiliary source wiring member 14 from the region in which the reverse recovery current Irr flows at a time of switching the upper arm 102, impact of the reverse recovery current Irr against the auxiliary source current Is that flows in the auxiliary source wiring member 14 can be reduced. Specifically, reduction in switching speed at a time of being turned on, which occurs due to the reverse recovery current Irr flowing in an opposite direction from the auxiliary source current Is, can be prevented. In this manner, turn-on losses in the upper arm 102 can be reduced.

In addition, in the semiconductor module 100 of the present example, by carefully considering placement of the semiconductor devices, lengths of the auxiliary source wiring member 14 and the auxiliary source wiring member 24 can be made equal, and thereby difference in switching losses between the upper arm and the lower arm can be reduced. For example, in the semiconductor module 100, by placing the switching device 10 and the switching device 20 such that they face each other in the Y axis direction, switching speeds of the upper arm and the lower arm can be made equal.

FIG. 1C illustrates one example of a cross section a-a′ of the semiconductor assembly 160 illustrated in FIG. 18. The laminated substrate 150 includes an insulating plate 151, the circuit plate 152, and a metal plate 153.

The insulating plate 151 is formed of a flat insulating material having an upper surface and a lower surface, and having an arbitrary thickness in a Z axis direction. The main surface of the laminated substrate 150 may be the upper surface of the insulating plate 151. The insulating plate 151 may be formed of a ceramic material such as aluminum oxide (Al₂O₃), aluminum nitride (AlN), or silicon nitride (Si₃N₄). The insulating plate 151 may be formed of a resin material such as epoxy, an epoxy resin material using a ceramic material as a filler, or the like.

The circuit plate 152 is a conductive member having an arbitrary thickness in the Z axis direction and provided on the upper surface of the insulating plate 151. The metal plate 153 is a conductive member having an arbitrary thickness in the Z axis direction and provided on the lower surface of the insulating plate 151. The circuit plate 152 and the metal plate 153 may be formed of plates containing metal materials such as copper and copper alloy. The circuit plate 152 and the metal plate 153 may be fixed to the insulating plate 151 by means of solder, flux, or the like. The metal plate 153 may be formed of a thermally conductive material such as copper or aluminum and function as a heat sink.

FIG. 1D is a main circuit diagram of the semiconductor module 100 according to an embodiment. For example, the semiconductor module 100 functions as a part of an in-vehicle unit that drives a motor of a vehicle. The semiconductor module 100 of the present example is composed of three legs which are a leg U-INV, a leg V-INV, and a leg W-INV. Each switching device may be alternately switched by a signal input to the control terminal of the semiconductor module 100 to function as a three-phase AC inverter circuit.

The leg U-INV is composed of one pair of a switching device 10U and a diode device 15U, and one pair of a switching device 20U and a diode device 25U. The leg V-INV is composed of one pair of a switching device 10y and a diode device 15V, and one pair of a switching device 20V and a diode device 25V. The leg W-INV is composed of one pair of a switching device 10W and a diode device 15W, and one pair of a switching device 20W and a diode device 25W.

An upper arm 102 is composed of three switching devices 10U to 10W and three diode devices 15U to 15W. A lower arm 104 is composed of three switching devices 20U to 20W and three diode devices 25U to 25W.

Each drain electrode of the switching devices 10U, 10y, and 10W is electrically connected to a positive electrode terminal 132. Similarly, each cathode electrode of the diode devices 15U, 15V, and 15W is electrically connected to the positive electrode terminal 132.

Source electrodes of the switching devices 10U, 10V, and 10W are electrically connected to an output terminal 110U, an output terminal 110V, or an output terminal 110W, respectively. Similarly, anode electrodes of the diode devices 15U, 15V, and 15W are electrically connected to the output terminals 110U, 110V, or 110W, respectively.

Each source electrode of the switching devices 20U, 20V, and 20W is electrically connected to a negative electrode terminal 134. Similarly, each anode electrode of the diode devices 25U, 25V, and 25W is electrically connected to the negative electrode terminal 134.

Drain electrodes of the switching devices 20U, 20V, and 20W are electrically connected the output terminals 110U, 110V, or 110W, respectively. Similarly, cathode electrodes of the diode devices 25U, 25V, and 25W are electrically connected to the output terminals 110U, 110V, or 110W, respectively.

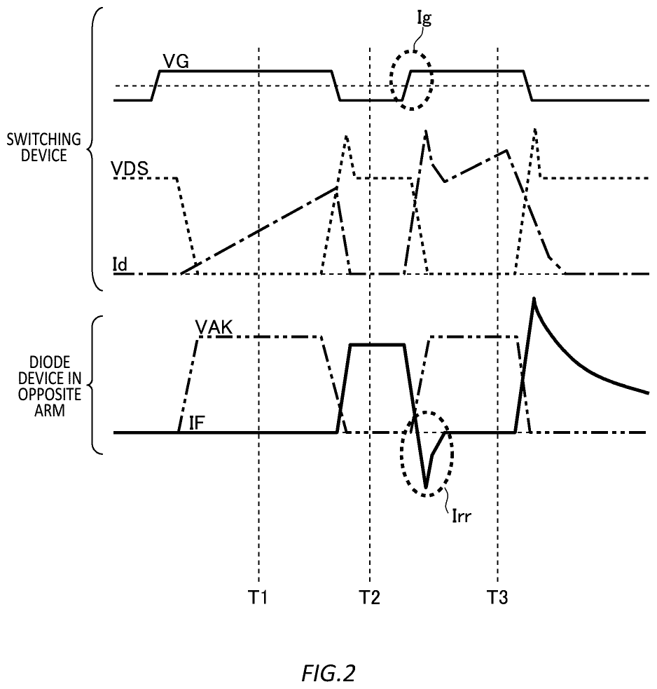

FIG. 2 illustrates current/voltage characteristics at times of switching of the semiconductor module 100. The present drawing shows a gate voltage VG, a drain-source voltage VDS, and a drain current Id of the switching device 10. The present drawing also shows an anode-cathode voltage VAK and a forward current IF of the diode device 25.

With regard to circuit states which correspond to time T1 to time T3, they will be described later. Between time T2 and time T3, in response to the gate current Ig being supplied and thus the switching device 10 being turned on, the reverse recovery current Irr flows in an arm opposite to the switching device 10.

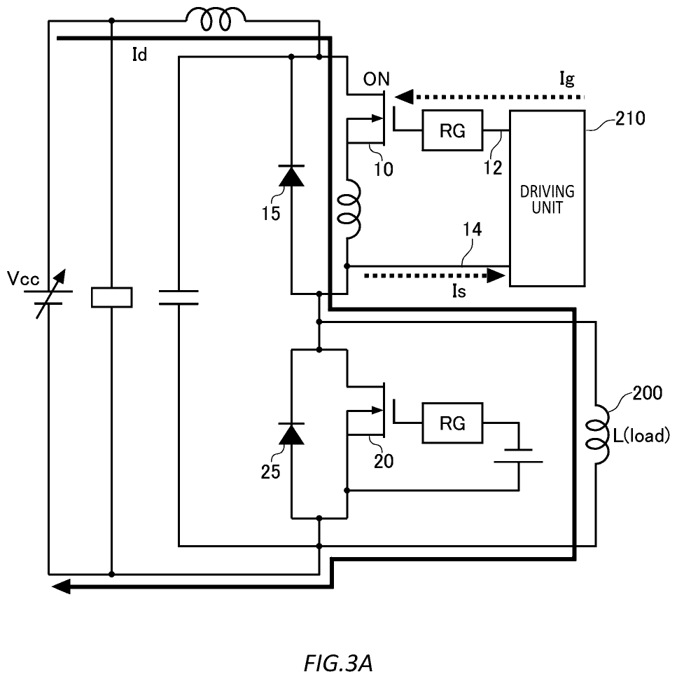

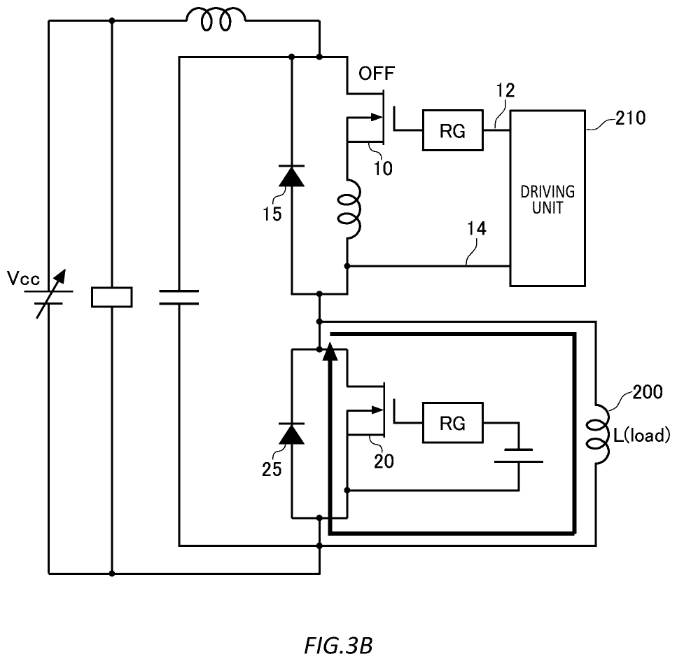

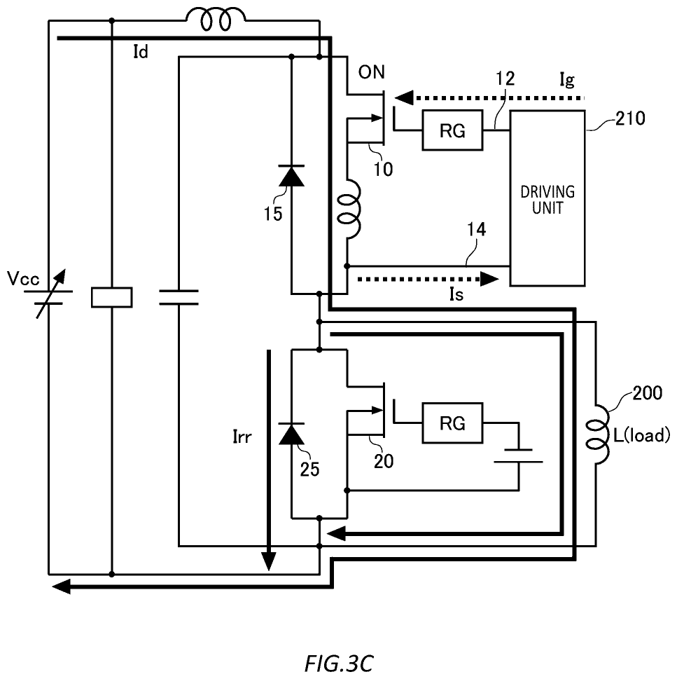

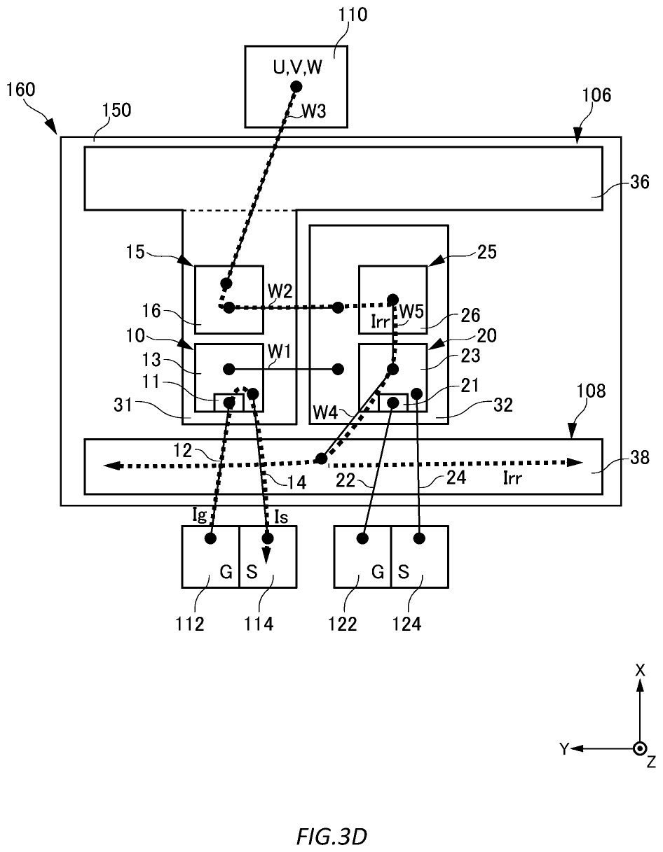

FIG. 3A is a circuit diagram taken at time T1 of FIG. 2, which shows an ON state of the switching device 10 placed in the upper arm 102. When the switching device 10 is turned on by a driving unit 210, a drain current Id flows into a load 200 with a constant di/dt through inductance. Here, a relationship ΔV=LdId/dt holds, meaning that dId/dt=ΔV/L=constant.

FIG. 3B is a circuit diagram taken at time T2 of FIG. 2, which shows an OFF state of the switching device 10 placed in the upper arm 102. When the switching device 10 is turned off, inductance directs current to flow in a direction that opposes the change in current. Then, a loop current flows through the diode device 25 placed in the lower arm 104. Note that, if the switching device 10 placed in the upper arm 102 is in the OFF state, the switching device 20 placed in the lower arm 104 is turned on except in a dead time period, whereas no current flows in this switching device 20 due to impact from the loop current.

FIG. 3C is a circuit diagram taken from time T2 to time T3 of FIG. 2, which shows an ON state of the switching device 10 placed in the upper arm 102. The driving unit 210 of the present example supplies a gate of the switching device 10 placed in the upper arm 102 with a gate current Ig. In this manner, the switching device 10 is turned on, and currents obtained by adding a loop current to a drain current Id from the switching device 10 flow into the load 200. Then, a reverse recovery current Irr is generated in the diode device 25 placed in the lower arm 104.

FIG. 3D is one example of a top view of the semiconductor assembly 160 with a reverse recovery current Irr flowing in a lower arm 104 in response to the upper arm 102 being turned on. The semiconductor assembly 160 of the present example is the same as the semiconductor assembly 160 illustrated in FIG. 18. The present drawing shows paths with dashed lines in which a gate current Ig, an auxiliary source current Is, and a reverse recovery current Irr flow. In the present example, the gate current Ig flows in the gate wiring member 12, and the auxiliary source current Is flows in the auxiliary source wiring member 14. The reverse recovery current Irr passes through the wire members W3 and W2 from the output terminal 110, and through the wire members W5 and W4 from the diode device 25, and then flows into the N type wiring portion 108.

The gate current Ig and the auxiliary source current Is of the present example can avoid impact from the reverse recovery current Irr by passing through paths different from the path of the reverse recovery current Irr. The gate wiring member 12 and the auxiliary source wiring member 14 of the present example are physically separated from the wire members W5 and W4 and the N type wiring portion 108 in which the reverse recovery current Irr flows. In this manner, switching losses of the semiconductor module 100 can be reduced.

The paths in which the gate current Ig and the auxiliary source current Is flow are placed not to be parallel with the path in which the reverse recovery current Irr flows. The wire member W4 in which the reverse recovery current Irr flows may be diagonally wired against the X axis direction. The wire member W5 is provided substantially parallel with the X axis direction, but the wire member W5 may be placed not to face the gate wiring member 12 and the auxiliary source wiring member 14 in the Y axis direction. Like this, by carefully considering current paths in which the gate current Ig, the auxiliary source current Is, and the reverse recovery current Irr flow, it is expected to prevent flows of the gate current Ig and the auxiliary source current Is from being obstructed by an induced magnetic field of the reverse recovery current Irr. In this manner, it is expected that switching losses will be reduced, and averaging ON times will be easier.

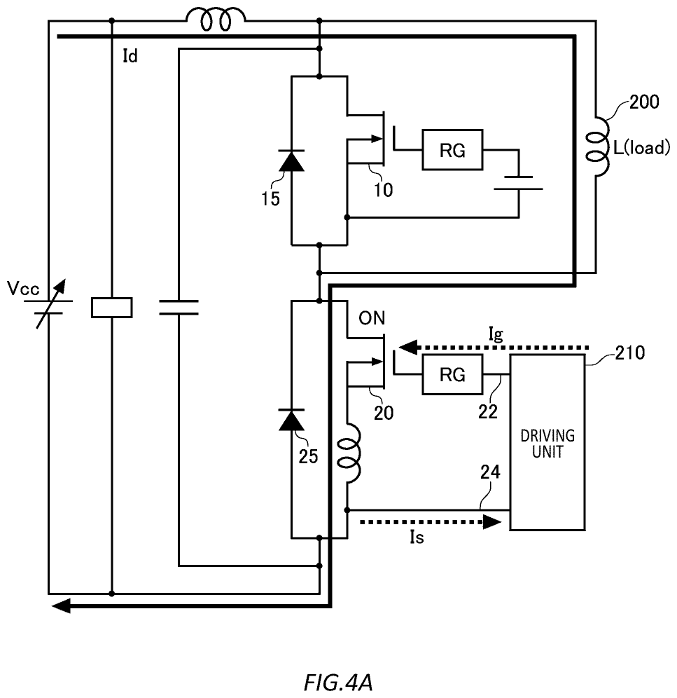

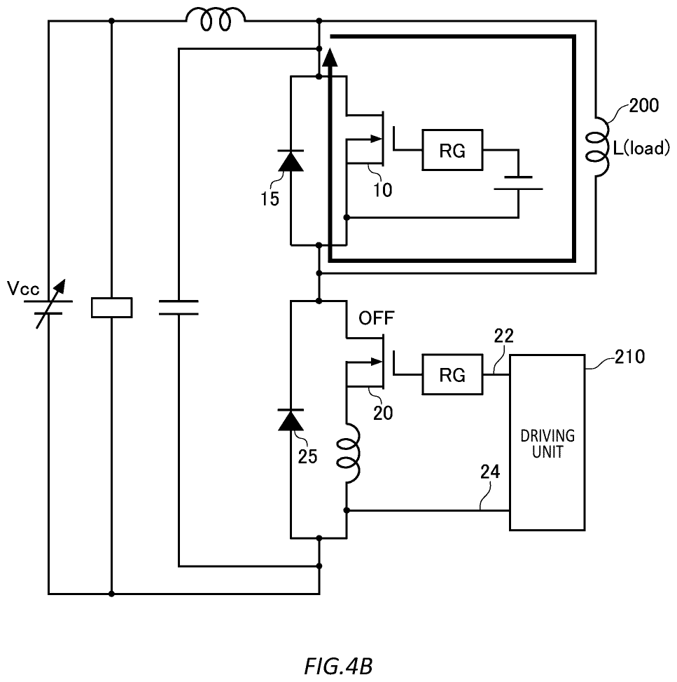

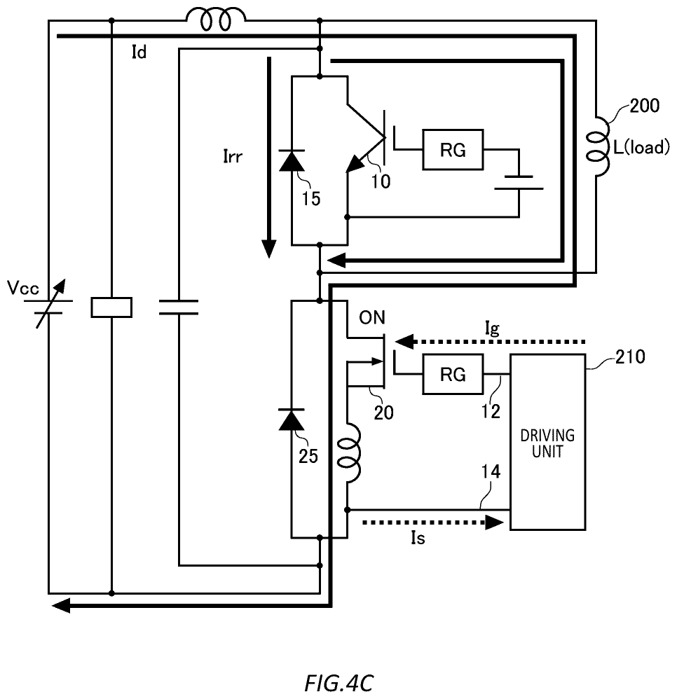

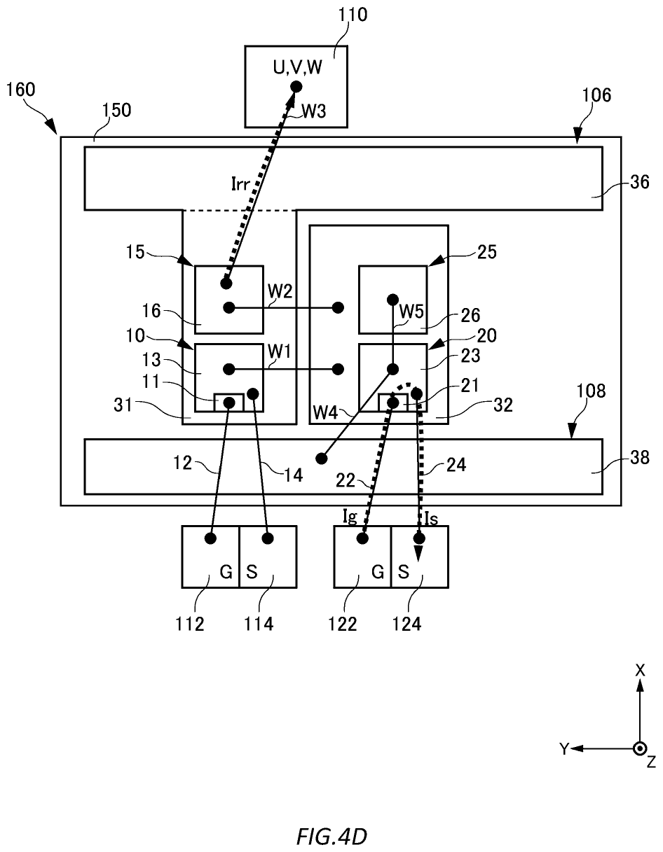

FIG. 4A is a circuit diagram taken at time T1 of FIG. 2, which shows an ON state of the switching device 20 placed in the lower arm 104. That is, FIGS. 3A and 4A are different in whether the upper arm 102 is made conductive or the lower arm 104 is made conductive. In the present example, when the switching device 20 is turned on by a driving unit 210, a drain current Id flows into a load 200 with a constant di/dt through inductance. Here, a relationship ΔV=LdId/dt holds, meaning that dId/dt=ΔV/L=constant.

FIG. 4B is a circuit diagram taken at time T2 of FIG. 2, which shows an OFF state of the switching device 20 placed in the lower arm 104. When the switching device 20 is turned off, inductance directs current to flow in a direction that opposes the change in current. Then, a loop current flows through the diode device 15 placed in the upper arm 102. Note that, if the switching device 20 placed in the lower arm 104 is in the OFF state, the switching device 10 placed in the upper arm 102 is turned on except in a dead time period, whereas no current flows in this switching device 10 due to impact from the loop current.

FIG. 4C is a circuit diagram taken from time T2 to time T3 of FIG. 2, which shows an ON state of the switching device 20 placed in the lower arm 104. The driving unit 210 in the present example supplies the switching device 20 placed in the lower arm 104 with a gate current Ig. In this manner, the switching device 20 is turned on, and currents obtained by adding a loop current to a drain current Id from the switching device 20 flows into the load 200. Then, a reverse recovery current Irr is generated in the diode device 15 placed in the upper arm 102.

FIG. 4D is one example of a top view of the semiconductor assembly 160 with a reverse recovery current Irr flowing in the upper arm 102 in response to the lower arm 104 being turned on. The semiconductor assembly 160 of the present example is the same as the semiconductor assembly 160 illustrated in FIG. 18. The present drawing shows paths with dashed lines in which a gate current Ig, an auxiliary source current Is, and a reverse recovery current Irr flow. In the present example, the gate current Ig flows in the gate wiring member 22, and the auxiliary source current Is flows in the auxiliary source wiring member 24. The reverse recovery current Irr passes through the circuit plate 36, the diode device 15, and the wire member W3, and then flows into the output terminal 110.

Similar to the case shown in FIG. 3D, the gate current Ig and the auxiliary source current Is of the present example can avoid impact from the reverse recovery current Irr by passing through paths different from the path of the reverse recovery current Irr. The gate wiring member 22 and the auxiliary source wiring member 24 of the present example are physically separated from the wire members W2 and W3 in which the reverse recovery current Irr flows. In this manner, switching losses of the semiconductor module 100 can be reduced.

The paths in which the gate current Ig and the auxiliary source current Is flow are placed not to be parallel with the path in which the reverse recovery current Irr flows. The wire member W2 in which the reverse recovery current Irr flows may be wired substantially parallel with the Y axis direction so that the wire member W2 is not parallel with the gate wiring member 22 and the auxiliary source wiring member 24. The wire member W3 is diagonally provided against the X axis direction. Like this, by carefully considering current paths in which the gate current Ig, the auxiliary source current Is, and the reverse recovery current Irr flow, it is expected to prevent flows of the gate current Ig and the auxiliary source current Is from being obstructed by an induced magnetic field of the reverse recovery current Irr. In this manner, it is expected that switching losses will be reduced, and averaging ON times will be easier.

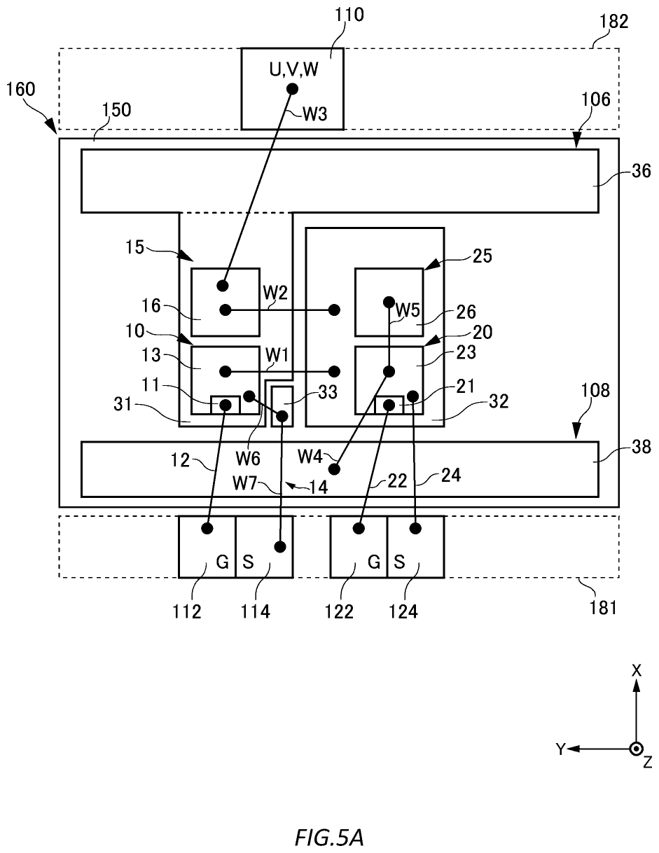

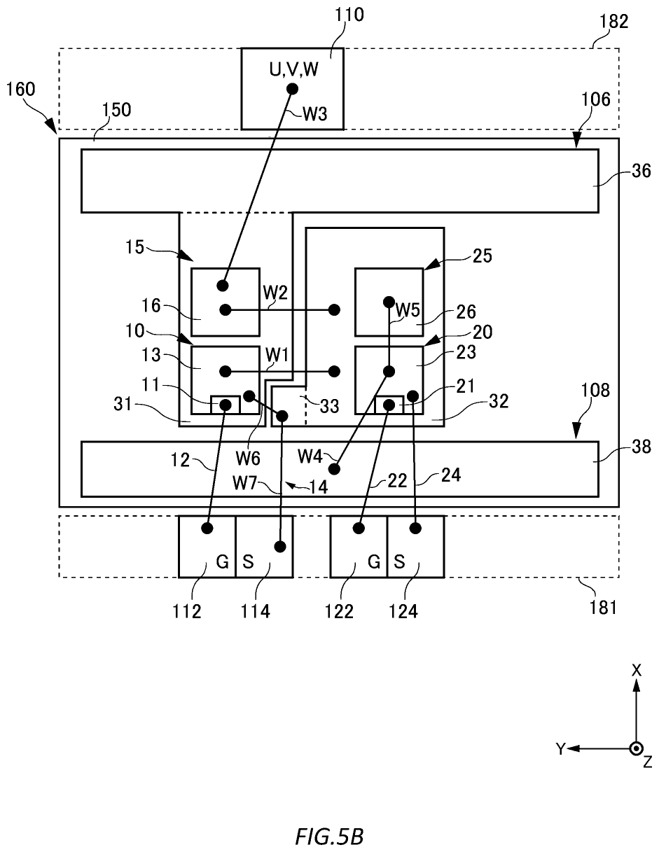

FIG. 5A is an enlarged view of a variant example of the semiconductor assembly 160. In a semiconductor assembly 160 of the present example, an auxiliary source wiring member 14 and an auxiliary source external terminal 114 are connected by a connection method different from that of the embodiment shown in FIG. 1B. In the present example, points different from the embodiment shown in FIG. 1B will be described in particular.

The auxiliary source wiring member 14 includes a wire member W6, a circuit plate 33, and a wire member W7. The wire member W6 connects a source electrode 13 and the circuit plate 33. The wire member W7 connects the circuit plate 33 and the auxiliary source external terminal 114. The circuit plate 33 is one example of a circuit plate 152 provided on a laminated substrate 150.

The auxiliary source wiring member 14 is physically separated from an output wiring line between a drain electrode of a switching device 20 and an output terminal 110. In other words, the circuit plate 33 of the present example is provided to be physically separated from a circuit plate 32 on the laminated substrate 150. Like this, the circuit plate 32 and the circuit plate 33 are placed so that a path in which an auxiliary source current Is flows and a path of a current that flows in the output wiring line do not overlap together. In this manner, impact of a reverse recovery current Irr that flows in the circuit plate 32 against the auxiliary source wiring member 14 can be avoided.

FIG. 5B is an enlarged view of a variant example of the semiconductor assembly 160. A semiconductor assembly 160 of the present example is different from the embodiment shown in FIG. 5A in that a circuit plate 33 is physically connected to a circuit plate 32. In the present example, points different from those of the embodiment shown in FIG. 5A will be described in particular.

An auxiliary source wiring member 14 is not physically separated from an output wiring line between a drain electrode of a switching device 20 and an output terminal 110. In other words, the auxiliary source wiring member 14 of the present example connects a source electrode 13 and an auxiliary source external terminal 114 via a circuit plate 152 on which the drain electrode of the switching device 20 is placed. Specifically, the auxiliary source wiring member 14 connects the source electrode 13 and the auxiliary source external terminal 114 via the circuit plate 33 integrally formed with the circuit plate 32 on which the drain electrode of the switching device 20 is placed.

As above, the circuit plate 33 of the present example is integrally formed with the circuit plate 32 on a laminated substrate 150, thus not physically separated from the circuit plate 32. However, the auxiliary source wiring member 14 is placed so that an auxiliary source current Is does not to receive impact from current that flows in the output wiring line. In other words, the circuit plate 33 is provided at a position different from a main path of the current that flows from the drain electrode of the switching device 20 to the output terminal 110. The circuit plate 32 and the circuit plate 33 may be placed such that a path in which the auxiliary source current Is flows and a path of the current which flows in the output wiring line do not overlap together.

For example, the circuit plate 33 is provided extruding from the circuit plate 32. An area of the circuit plate 33 may be smaller than an area of the circuit plate 32. The circuit plate 33 may be provided between a switching device 10 and the switching device 20 in the Y axis direction. The circuit plate 33 may be provided in a region except a region connecting the drain electrode of the switching device 20 and the output terminal 110 in the XY plane.

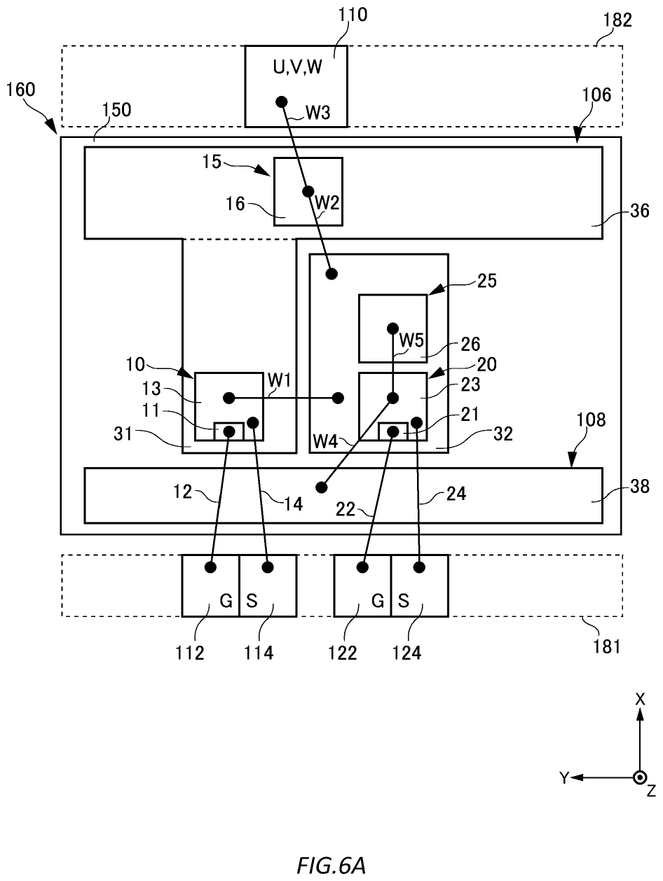

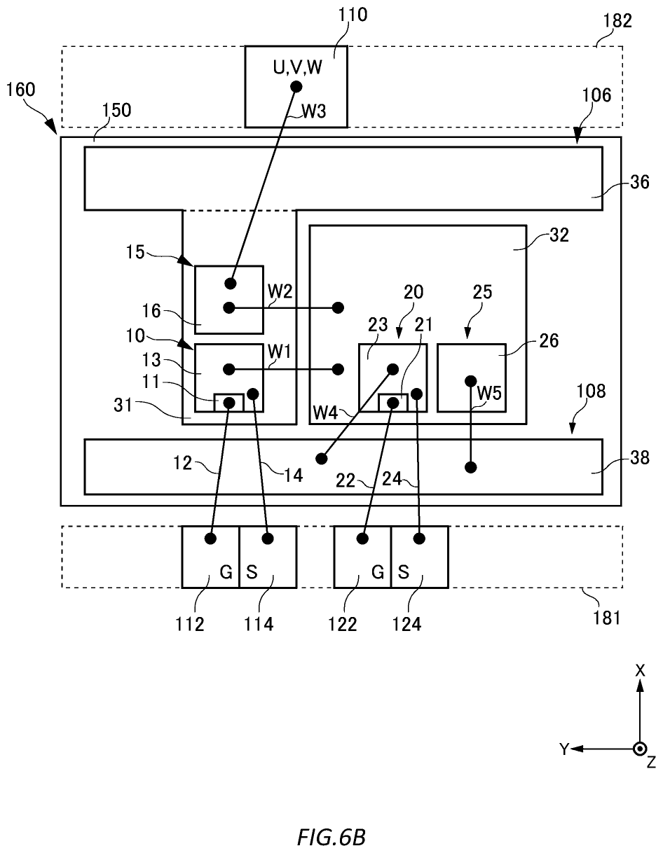

FIG. 6A is an enlarged view of a variant example of the semiconductor assembly 160. A semiconductor assembly 160 of the present example has a diode device 15 placed at a position different from that of the embodiment shown in FIG. 18. The diode device 15 of the present example is mounted in a P type wiring portion 106 that is a first wiring portion. In the present example, points different from the embodiment shown in FIG. 18 will be described in particular.

The diode device 15 is provided on a circuit plate 36 of the P type wiring portion 106. The diode device 15 of the present example is provided in an extending portion of the P type wiring portion 106 in an upper arm 102. An output terminal 110 is electrically connected to a circuit plate 32 of a lower arm 104 via the diode device 15. The output terminal 110 is connected to an anode electrode 16 of the diode device 15 by means of a wire member W3. The anode electrode 16 is connected to the circuit plate 32 by means of a wire member W2. In this manner, a diode device 25 provided in the lower arm 104 is connected to the output terminal 110 via the diode device 15 provided in the upper arm 102.

FIG. 6B is an enlarged view of a variant example of the semiconductor assembly 160. A semiconductor assembly 160 of the present example has a diode device 25 placed at a position different from that of the embodiment shown in FIG. 18. In the present example, points different from the embodiment shown in FIG. 18 will be described in particular.

A switching device 20 and the diode device 25 are provided in the lower arm 104, so as to face each other in the Y axis direction. The diode device 25 of the present example is provided farther toward a negative side of the Y axis direction than the switching device 20. The diode device 25 is connected to a circuit plate 38 of an N type wiring portion 108 by means of a wire member W5 that connects an anode electrode 26 and the circuit plate 38.

Like this, positions at which a switching device and a diode device are provided may be suitably changed according to a layout request for a semiconductor module 100. In the semiconductor module 100 of the present example, a semiconductor device provided in an upper arm 102 and a semiconductor device provided in the lower arm 104 are provided facing each other in the Y axis direction, and thereby switching losses can be reduced. Like this, even if a position of the semiconductor device provided on a laminated substrate 150 is changed, impact of a reverse recovery current Irr against an auxiliary source wiring member 14 can be avoided.

While the present invention has been described by means of the embodiments, the technical scope of the present invention is not limited to the above described embodiments. It is apparent to persons skilled in the art that various alterations or improvements can be made to the above described embodiments. It is also apparent from the scope of the claims that the embodiments added with such alterations or improvements can be included in the technical scope of the present invention.

Note that the operations, procedures, steps, stages etc. of each process performed by an apparatus, system, program, and method shown in the claims, specification, or drawings can be performed in any order as long as the order is not clearly indicated by “prior to,” “before,” or the like and as long as the output from a previous process is not used in a later process. Even if the operational flow is described using phrases such as “first” or “next” in the claims, specification, or drawings, it does not necessarily mean that the process must be performed in this order.

### EXPLANATION OF REFERENCES

10: switching device;
11: gate electrode;
12: gate wiring member;
13: source electrode;
14: auxiliary source wiring member;
15: diode device;
16: anode electrode;
20: switching device;
21: gate electrode;
22: gate wiring member;
23: source electrode;
24: auxiliary source wiring member;
25: diode device;
26: anode electrode;
31: circuit plate;
32: circuit plate;
33: circuit plate;
36: circuit plate;
38: circuit plate;
100: semiconductor module;
102: upper arm;
104: lower arm;
106: P type wiring portion;
108: N type wiring portion;
110: output terminal;
112: gate external terminal;
114: auxiliary source external terminal;
122: gate external terminal;
124: auxiliary source external terminal;
132: positive electrode terminal;
134: negative electrode terminal;
150: laminated substrate;
151: insulating plate;
152: circuit plate;
153: metal plate;
160: semiconductor assembly;
170: housing;
181: first placement region;
182: second placement region;
183: third placement region;
200: load;
210: driving unit.

What is claimed is:

1. A semiconductor module, comprising:
a first switching device provided in one of an upper arm or a lower arm;
a second switching device provided in another of the upper arm or the lower arm;
a first diode device connected in parallel with the first switching device;
a second diode device connected in parallel with the second switching device;
a laminated substrate of which a main surface has two sides extending in a predetermined first direction and a predetermined second direction;
a gate external terminal and an auxiliary source external terminal which are provided farther toward a negative side of the first direction than the upper arm and the lower arm, and arranged in the second direction;
a P type wiring portion connected to a positive electrode terminal; and
an N type wiring portion connected to a negative electrode terminal, wherein
the first switching device, the second switching device, the first diode device, and the second diode device are provided on the laminated substrate,
at least one of the first switching device or the first diode device is provided facing at least one of the second switching device or the second diode device in the second direction, and
the first switching device and the second switching device are placed between the P type wiring portion and the N type wiring portion in the first direction.

2. The semiconductor module according to claim 1, wherein
an auxiliary source wiring member connected to a source electrode of the first switching device is physically separated from an output wiring line between a drain electrode of the second switching device and an output terminal.

3. The semiconductor module according to claim 2, wherein
the auxiliary source wiring member of the first switching device directly connects the source electrode of the first switching device and the auxiliary source external terminal.

4. The semiconductor module according to claim 1, wherein
an auxiliary source wiring member connected to a source electrode of the first switching device is not physically separated from an output wiring line between a drain electrode of the second switching device and an output terminal.

5. The semiconductor module according to claim 4, wherein
the auxiliary source wiring member of the first switching device connects the source electrode of the first switching device and the auxiliary source external terminal via a conductive circuit plate on which the drain electrode of the second switching device is placed.

6. The semiconductor module according to claim 1, wherein
the first switching device and the second switching device are provided facing each other in the second direction.

7. The semiconductor module according to claim 1, wherein
the first switching device and the first diode device are provided facing each other in the first direction.

8. The semiconductor module according to claim 1, wherein
the first diode device and the second diode device are provided facing each other in the second direction.

9. The semiconductor module according to claim 1, wherein
the second switching device and the second diode device are provided in the lower arm, so as to face each other in the second direction.

10. The semiconductor module according to claim 1, wherein:
the first switching device is provided farther toward the negative side of the first direction than the first diode device; and
the second switching device is provided farther toward the negative side of the first direction than the second diode device.

11. The semiconductor module according to claim 1, wherein
the P type wiring portion is provided between the N type wiring portion and an output terminal in the first direction.

12. The semiconductor module according to claim 1, wherein
each of the P type wiring portion and the N type wiring portion has an extending portion extending in the second direction.

13. The semiconductor module according to claim 12, wherein
the first diode device is provided in the extending portion of the P type wiring portion.

14. The semiconductor module according to claim 1, comprising
an output terminal provided farther toward a positive side of the first direction than the upper arm and the lower arm.

15. The semiconductor module according to claim 14, wherein
the second switching device is provided in the lower arm, and connected to the output terminal via the first diode device provided in the upper arm.

16. A semiconductor module, comprising:
a first switching device provided in one of an upper arm or a lower arm;
a second switching device provided in another of the upper arm or the lower arm;
a first diode device connected in parallel with the first switching device;
a second diode device connected in parallel with the second switching device;
a laminated substrate of which a main surface has two sides extending in a predetermined first direction and a predetermined second direction;
a first wiring portion connected to one of a positive electrode terminal or a negative electrode terminal, and extending in the second direction;
a second wiring portion connected to another of the positive electrode terminal or the negative electrode terminal, and extending in the second direction;
multiple gate external terminals provided in a first placement region extending in the second direction, and electrically connected to a gate electrode of the first switching device or a gate electrode of the second switching device;
multiple auxiliary source external terminals provided in the first placement region, and electrically connected to a source electrode of the first switching device or a source electrode of the second switching device;
a first gate wiring member which connects the gate electrode of the first switching device and a corresponding gate external terminal among the multiple gate external terminals;
a first auxiliary source wiring member which connects the source electrode of the first switching device and a corresponding auxiliary source external terminal among the multiple auxiliary source external terminals;
a second gate wiring member which connects the gate electrode of the second switching device and a corresponding gate external terminal among the multiple gate external terminals; and
a second auxiliary source wiring member which connects the source electrode of the second switching device and a corresponding auxiliary source external terminal among the multiple auxiliary source external terminals, wherein
the first switching device and the second switching device are provided facing each other in the second direction, and
the first switching device and the second switching device are provided such that the second wiring portion is sandwiched between the first switching device and the second switching device, and the first placement region.

17. The semiconductor module according to claim 16, comprising
an output terminal provided in a second placement region extending in the second direction, wherein
the first switching device and the second switching device are provided such that the first wiring portion is sandwiched between the first switching device and the second switching device, and the second placement region.

18. The semiconductor module according to claim 16, comprising
three legs each of which is composed of the upper arm and the lower arm.

19. The semiconductor module according to claim 18, wherein
the positive electrode terminal and the negative electrode terminal are provided in a third placement region placed side by side with the three legs in the second direction.

20. The semiconductor module according to claim 19, wherein
each of the three legs has the upper arm connected to an output terminal over the first wiring portion by means of a wire member.

21. The semiconductor module according to claim 16, wherein
the first switching device and the second switching device are placed between the first wiring portion and the second wiring portion in the first direction.

22. The semiconductor module according to claim 16, wherein:
the first wiring portion is a P type wiring portion connected to the positive electrode terminal; and
the second wiring portion is an N type wiring portion connected to the negative electrode terminal.

23. The semiconductor module according to claim 16, comprising:
a first circuit plate for constituting the upper arm; and
a second circuit plate for constituting the lower arm, wherein
the first diode device is mounted on the first circuit plate, and
the second diode device is mounted on the second circuit plate.

24. The semiconductor module according to claim 16, comprising:
a first circuit plate for constituting the upper arm; and
a second circuit plate for constituting the lower arm, wherein
the first diode device is mounted in the first wiring portion, and
the second diode device is mounted on the second circuit plate.

25. The semiconductor module according to claim 16, wherein
the gate electrode of the first switching device is provided facing the gate electrode of the second switching device in the second direction.

26. The semiconductor module according to claim 16, wherein
a connection point for the first auxiliary source wiring member and the source electrode of the first switching device faces a connection point for the second auxiliary source wiring member and the source electrode of the second switching device in the second direction.

27. The semiconductor module according to claim 16, wherein:
the first diode device is provided such that the first switching device is sandwiched between the first diode device and the second wiring portion; and
the second diode device is provided such that the second switching device is sandwiched between the second diode device and the second wiring portion.

28. The semiconductor module according to claim 1, wherein:
the first switching device and the first diode device are placed in the upper arm; and
the second switching device and the second diode device are placed in the lower arm.

29. The semiconductor module according to claim 1, comprising
multiple upper arms and multiple lower arms, wherein
switching devices of the multiple upper arms and switching devices of the multiple lower arms are alternately arranged one by one in the second direction.

30. The semiconductor module according to claim 1, wherein:
the first switching device and the second switching device are silicon carbide metal-oxide-semiconductors; and
the first diode device and the second diode device are silicon carbide Schottky barrier diodes.

31. A semiconductor module, comprising:
a first switching device provided in one of an upper arm or a lower arm;
a second switching device provided in another of the upper arm or the lower arm;
a first diode device connected in parallel with the first switching device;
a second diode device connected in parallel with the second switching device;
a laminated substrate of which a main surface has two sides extending in a predetermined first direction and a predetermined second direction;
a gate external terminal and an auxiliary source external terminal which are provided farther toward a negative side of the first direction than the upper arm and the lower arm, and arranged in the second direction;
a P type wiring portion connected to a positive electrode terminal and the upper arm;
an N type wiring portion connected to a negative electrode terminal and the lower arm; and
an output terminal connected to the upper arm and the lower arm, wherein
the first switching device, the second switching device, the first diode device, and the second diode device are provided on the laminated substrate,
at least one of the first switching device or the first diode device is provided facing at least one of the second switching device or the second diode device in the second direction,
the semiconductor module has a first side extending in the first direction, a second side facing the first side and extending in the first direction, a third side extending in the second direction, and a fourth side facing the third side and extending in the second direction in a planar view,
the positive electrode terminal and the negative electrode terminal are provided on the first side,
the gate external terminal and the auxiliary source external terminal are provided on the third side, and
the output terminal is provided on the fourth side.

32. The semiconductor module according to claim 31, wherein
an auxiliary source wiring member connected to a source electrode of the first switching device is physically separated from an output wiring line between a drain electrode of the second switching device and the output terminal.

33. The semiconductor module according to claim 32, wherein
the auxiliary source wiring member of the first switching device directly connects the source electrode of the first switching device and the auxiliary source external terminal.

34. The semiconductor module according to claim 31, wherein
an auxiliary source wiring member connected to a source electrode of the first switching device is not physically separated from an output wiring line between a drain electrode of the second switching device and the output terminal.

35. The semiconductor module according to claim 34, wherein
the auxiliary source wiring member of the first switching device connects the source electrode of the first switching device and the auxiliary source external terminal via a conductive circuit plate on which the drain electrode of the second switching device is placed.

36. The semiconductor module according to claim 31, wherein
the first switching device and the second switching device are provided facing each other in the second direction.

37. The semiconductor module according to claim 31, wherein
the first switching device and the first diode device are provided facing each other in the first direction.

38. The semiconductor module according to claim 31, wherein
the first diode device and the second diode device are provided facing each other in the second direction.

39. The semiconductor module according to claim 31, wherein
the second switching device and the second diode device are provided in the lower arm, so as to face each other in the second direction.

40. The semiconductor module according to claim 31, wherein:
the first switching device is provided farther toward the negative side of the first direction than the first diode device; and
the second switching device is provided farther toward the negative side of the first direction than the second diode device.

41. The semiconductor module according to claim 31, wherein
the first switching device and the second switching device are placed between the P type wiring portion and the N type wiring portion in the first direction.

42. The semiconductor module according to claim 41, wherein
the P type wiring portion is provided between the N type wiring portion and the output terminal in the first direction.

43. The semiconductor module according to claim 41, wherein
each of the P type wiring portion and the N type wiring portion has an extending portion extending in the second direction.

44. The semiconductor module according to claim 43, wherein
the first diode device is provided in the extending portion of the P type wiring portion.

45. The semiconductor module according to claim 31, comprising
the output terminal provided farther toward a positive side of the first direction than the upper arm and the lower arm.

46. The semiconductor module according to claim 45, wherein
the second switching device is provided in the lower arm, and connected to the output terminal via the first diode device provided in the upper arm.
